(19) United States
(12) Patent Application Publication
(10) Pub. No.: US 2025/0183224 A1
(43) Pub. Date: Jun. 5, 2025

(54) SEMICONDUCTOR PACKAGE AND METHOD FOR MANUFACTURING THE SAME

(71) Applicant: SAMSUNG ELECTRONICS CO., LTD., Suwon-si (KR)

(72) Inventors: JIN-WOO PARK, Suwon-si (KR); Un-Byoung Kang, Suwon-si (KR)

(73) Assignee: SAMSUNG ELECTRONICS CO., LTD., Suwon-si (KR)

(21) Appl. No.: 18/903,644

(22) Filed: Oct. 1, 2024

(30) Foreign Application Priority Data
Dec. 5, 2023 (KR) 10-2023-0174433

(51) Int. Cl. H01L 23/00; H01L 21/56; H01L 23/29; H01L 25/065; H10B 80/00

(52) U.S. Cl. CPC H01L 24/83; H01L 24/29; H01L 24/32; H01L 24/73; H01L 24/92; H01L 25/0655; H01L 21/56; H01L 23/296; H01L 24/16; H01L 24/81; H01L 2224/16227; H01L 2224/26175; H01L 2224/2929; H01L 2224/32225; H01L 2224/73204; H01L 2224/81986; H01L 2224/83007; H01L 2224/83102; H01L 2224/92125; H10B 80/00

(57) ABSTRACT

A semiconductor package according to one or more embodiments includes an interposer, a first semiconductor die and a second semiconductor die, the first and the second semiconductor dies being disposed on the interposer, a plurality of first connection members between the interposer and the first semiconductor die, a plurality of second connection members between the interposer and the second semiconductor die, a dam structure between the plurality of first connection members and the plurality of second connection members, an insulating member covering the plurality of first connection members between the interposer and the first semiconductor die, and a molding material covering the first semiconductor die, the second semiconductor die, and the plurality of second connection members on the interposer.

### CROSS-REFERENCE TO RELATED APPLICATION

This application claims priority to and the benefit of Korean Patent Application No. 10-2023-0174433 filed in the Korean Intellectual Property Office on Dec. 5, 2023, the disclosure of which are incorporated herein by reference in its entirety.

### BACKGROUND

### (a) Field

The present disclosure relates to a semiconductor package and a method for manufacturing the same.

### (b) Description of Related Art

A semiconductor package in the related art includes an application specific integrated circuit (ASIC) and a high bandwidth memory (HBM) and is manufactured through a flip chip bonding process that involves forming bumps on a pattern of the ASIC and on a pattern of the HBM, and then bonding the HBM and the ASIC on an interposer with the bumps therebetween.

The flip chip bonding process has disadvantages in that cracks may occur in the bumps or the bumps may fall off due to an external physical impact and an external environment (e.g., a temperature change, humidity, and dust). The bumps are protected from the external physical impact and an environment change by using an underfill technology of filling an insulating member in each between the interposer and the HBM and between the interposer and the ASIC.

In addition, the semiconductor package in the related art has a structure in which the HBM molded with a second molding material is molded again with a first molding material.

The first molding material, the second molding material, and the insulating member each have different physical properties. Consequently, adhesion weakens at an interface where the first molding material, the second molding material, and the insulating member meet. In addition, greater stress occurs on the outside of the semiconductor package than the center due to warpage characteristics that occur in the semiconductor package, which causes a delamination issue at a position where the insulating member between the interposer and the HBM disposed outside the ASIC on the interposer, the first molding material covering the HBM, and the second molding material within the HBM contact each other.

Therefore, there is a need to develop a new semiconductor package technology capable of improving such problems of the semiconductor package of the related art.

### SUMMARY

One or more embodiments of the present disclosure provide a semiconductor package in which a dam structure is disposed between first connection members disposed on a lower surface of a first semiconductor die and second connection members disposed on a lower surface of a second semiconductor die. Only the first connection members may be underfilled by using the dam structure as a barrier, and the second connection members may be covered with a molding material in a molding process.

Further, one or more embodiments of the present disclosure provide a method for manufacturing the semiconductor package.

A semiconductor package according to an embodiment includes an interposer, a first semiconductor die and a second semiconductor die on the interposer, a plurality of first connection members between the interposer and the first semiconductor die, a plurality of second connection members between the interposer and the second semiconductor die, a dam structure between the plurality of first connection members and the plurality of second connection members, an insulating member covering the plurality of first connection members between the interposer and the first semiconductor die, and a molding material covering the first semiconductor die, the second semiconductor die, and the plurality of second connection members on the interposer.

A semiconductor package according to an embodiment includes an interposer, a first semiconductor die and second semiconductor dies on the interposer, the second semiconductor dies comprising a first-side second semiconductor die (e.g., a left-side second semiconductor die) and a second-side second semiconductor die (e.g., a right-side second semiconductor die) that are positioned on two opposing sides (e.g., a left side and a right side) of the first semiconductor die to face each other across the first semiconductor die, a plurality of first connection members between the interposer and the first semiconductor die, a plurality of second connection members between the interposer and the first-side second semiconductor die, a plurality of third connection members between the interposer and the second-side second semiconductor die, a first dam structure on the interposer and between the plurality of first connection members and the plurality of second connection members, a second dam structure on the interposer and between the plurality of first connection members and the plurality of third connection members, an insulating member covering the plurality of first connection members between the interposer and the first semiconductor die, and a molding material covering the first semiconductor die, the first-side second semiconductor die, the second-side semiconductor die, and the plurality of second connection members on the interposer.

A method of manufacturing a semiconductor package according to an embodiment includes forming a plurality of first bonding pads and a plurality of second bonding pads on a substrate, forming a dam structure between the plurality of first bonding pads and the plurality of second bonding pads on the substrate, bonding a first semiconductor die to the plurality of first bonding pads by using a plurality of first connection members, and bonding a second semiconductor die to the plurality of second bonding pads by using a plurality of second connection members, applying an insulating member to cover the plurality of first bonding pads and the plurality of first connection members, and covering the first semiconductor die, the second semiconductor die, the plurality of second bonding pads, and the plurality of second connection members with a molding material on the substrate.

The problem that delamination occurs at a position where the insulating member between the interposer and the second semiconductor die disposed outside the first semiconductor die on the interposer, the molding material (first molding material) covering the second semiconductor die, and a second molding material within the second semiconductor die contact each other may be improved.

The second connection members between the second semiconductor die and the interposer may be covered with a molding material used in the molding process other than the insulating member. As a result, warpage occurring in the semiconductor package may be reduced, and residual stress inside the semiconductor package may be reduced. Accordingly, a bonding yield may be improved when a bonding process is performed on an external device, etc.

The second connection members between the second semiconductor die and the interposer may be covered with a molding material used in the molding process other than the insulating member. By not using the insulating member, the insulating member does not occupy the space of the keep out zone (KOZ) outside the second semiconductor die, and thus, the size of the interposer may be reduced, and the number of net dies within a wafer may be increased in a process of forming the interposer.

### BRIEF DESCRIPTION OF THE DRAWINGS

The above and/or other aspects will be more apparent by describing certain example embodiments, with reference to the accompanying drawings, in which:

FIG. 1 is a cross-sectional view showing a semiconductor package according to one or more embodiments;

FIG. 2 is a plan view showing a cross section of the semiconductor package of FIG. 1;

FIG. 3 is a cross-sectional view showing a step of forming first bonding pads and second bonding pads according to one or more embodiments;

FIGS. 4 to 12 are cross-sectional views for explaining a method of forming a dam structure according to one or more embodiments;

FIG. 13 is a cross-sectional view showing a step of mounting a first semiconductor die on an interposer base according to one or more embodiments;

FIG. 14 is a cross-sectional view showing a step of applying an insulating member according to one or more embodiments;

FIG. 15 is a cross-sectional view showing a step of mounting a second semiconductor die on the interposer base according to one or more embodiments;

FIG. 16 is a cross-sectional view showing a step of molding the first semiconductor die, the second semiconductor die, the dam structure on the interposer base according to one or more embodiments;

FIG. 17 is a cross-sectional view showing a step of performing a chemical mechanical polishing (CMP) process on a molding material according to one or more embodiments;

FIG. 18 is a cross-sectional view showing a step of removing a carrier from the interposer base according to one or more embodiments;

FIG. 19 is a cross-sectional view showing a step of forming connection pads and connection members on the interposer base according to one or more embodiments; and

FIG. 20 is a cross-sectional view showing a step of mounting the interposer on a substrate.

### DETAILED DESCRIPTION

Example embodiments are described in greater detail below with reference to the accompanying drawings.

In the following description, like drawing reference numerals are used for like elements, even in different drawings. The matters defined in the description, such as detailed construction and elements, are provided to assist in a comprehensive understanding of the example embodiments. However, it is apparent that the example embodiments can be practiced without those specifically defined matters. Also, well-known functions or constructions are not described in detail since they would obscure the description with unnecessary detail.

In addition, since the size and thickness of each component shown in the drawings are arbitrarily shown for convenience of description, the present disclosure is not necessarily limited to those shown.

In addition, throughout the specification, being “connected” does not only mean that two or more elements are “directly connected”, but may mean that two or more elements are “indirectly connected” through other elements. In addition, unless explicitly described to the contrary, the word “comprise”, and variations such as “comprises” or “comprising”, will be understood to imply the inclusion of stated elements but not the exclusion of any other elements.

In addition, it will be understood that when an element such as a layer, film, region, or substrate is referred to as being “on” another element, it may be directly on the other element or intervening elements may also be present. In contrast, when an element is referred to as being “directly on” another element, there are no intervening elements present. In addition, being “above” or “on” a reference part means being above or below the reference part, and does not necessarily mean being “above” or “on” in the opposite direction of gravity.

In addition, throughout the specification, when it is “on a plane” means when a target portion is viewed from above, and when it is “on a cross section” means when a cross section obtained by vertically cutting a target portion is viewed from the side.

Hereinafter, a semiconductor package 100 of one or more embodiments and a method for manufacturing the same will be described with reference to the drawings.

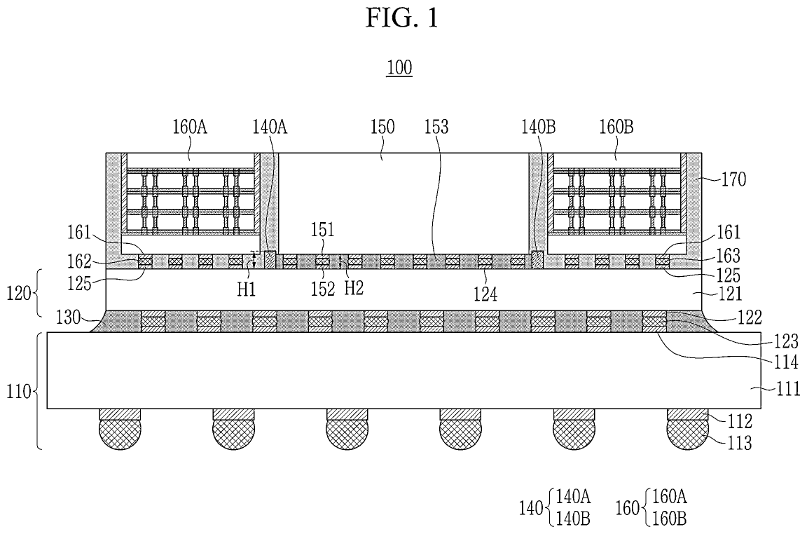

FIG. 1 is a cross-sectional view showing the semiconductor package 100 according to one or more embodiments.

Referring to FIG. 1, the semiconductor package 100 includes a substrate 110, an interposer 120, connection members 123, a first insulating member 130, a dam structure 140, a first semiconductor die 150, first connection members 152, second insulating members 153, one or more second semiconductor dies 160A and 160B, second connection members 162, third connection members 163, and a molding material 170. In one or more embodiments, the semiconductor package 100 may be a 2.5D semiconductor package. In one or more embodiments, the semiconductor package 100 may be manufactured based on fan out wafer level package (FOWLP) or fan out panel level package (FOPLP) technology.

The substrate 110 is disposed on a lower surface of the interposer 120. The substrate 110 may include a substrate base 111, external connection pads 112, external connection members 113, and bonding pads 114. In one or more embodiments, the substrate 110 may include a printed circuit board (PCB). The substrate 110 may be replaced with an interposer or wafer level semiconductor die.

The substrate base 111 includes an insulating layer and wiring layers and vias within the insulating layer. The external connection pads 112 are disposed on a lower surface of the substrate base 111. The external connection pads 112 are disposed between the wiring layer within the substrate base 111 and the external connection members 113. Each of the external connection pads 112 electrically connects the wiring layer within the substrate base 111 to the external connection member 113. In one or more embodiments, the external connection pad 112 may include at least one of copper, nickel, zinc, gold, silver, platinum, palladium, chromium, titanium, and an alloy thereof.

The external connection members 113 are disposed on lower surfaces of the external connection pads 112. Each of the external connection members 113 electrically connects the semiconductor package 100 to an external device. In one or more embodiments, the external connection member 113 may include at least one of tin, silver, lead, nickel, copper, or an alloy thereof. In one or more embodiments, the external connection member 113 may include a solder ball or micro bump.

The bonding pads 114 are disposed on an upper surface of the substrate base 111. The bonding pads 114 are electrically connected to the interposer 120 through the connection members 123.

In one or more embodiments, the bonding pad 114 may include at least one of copper, nickel, zinc, gold, silver, platinum, palladium, chromium, titanium, and an alloy thereof.

The interposer 120 is disposed on the substrate 110. The interposer 120 may include an interposer base 121, connection pads 122, first bonding pads 124, and second bonding pads 125. The interposer 120 may be an intermediate medium that electrically connects the first semiconductor die 150 and the second semiconductor die 160B, each having fine-interval I/O, to a substrate having normal-interval I/O. In one or more embodiments, the interposer 120 may include a silicon interposer, an organic interposer, or a composite interposer. In one or more embodiments, the composite interposer may include at least one of a silicon interposer, an organic interposer, a bridge die, and a surface mount device (SMD).

The interposer base 121 includes an insulating layer and wiring layers and vias within the insulating layer. The connection pads 122 are disposed on a lower surface of the interposer base 121. The connection pads 122 are disposed between the wiring layer within the interposer base 121 and the connection members 123. Each of the connection pads 122 electrically connects the wiring layer within the interposer base 121 to the connection member 123. In one or more embodiments, the connection pad 122 may include at least one of copper, nickel, zinc, gold, silver, platinum, palladium, chromium, titanium, and an alloy thereof.

The first bonding pads 124 are disposed on an upper surface of the interposer base 121. Each of the first bonding pads 124 is disposed below the first connection member 152 and is electrically connected to the first connection member 152. The second bonding pads 125 are disposed on the upper surface of the interposer base 121. Each of the second bonding pads 125 is disposed below the second connection member 162 or the third connection member 163 and is electrically connected to the second connection member 162 or the third connection member 163.

The connection members 123 are disposed on lower surfaces of the connection pads 122. Each of the connection members 123 electrically connects the connection pad 122 to the bonding pad 114. In one or more embodiments, the connection member 123 may include at least one of tin, silver, lead, nickel, copper, or an alloy thereof. In one or more embodiments, the connection member 123 may include a solder ball or micro bump.

The first insulating member 130 surrounds and protects the bonding pads 114, the connection pads 122, and the connection members 123 between the substrate 110 and the interposer 120. In one or more embodiments, the first insulating member 130 may include a non-conductive film (NCF). In one or more embodiments, the first insulating member 130 may include non-conductive paste (NCP). In one or more embodiments, the first insulating member 130 may include a capillary underfill (CUF).

The dam structure 140 is disposed on the upper surface of the interposer base 121. In a process of underfilling the first bonding pads 124, the first connection members 152, and first connection pads 151 below the first semiconductor die 150 with an insulating member by performing a CUF process, the dam structure 140 acts as a barrier structure to prevent the insulating member from flowing towards the second connection members 162 (below the second semiconductor die 160A) and the third connection members 163 (below the second semiconductor die 160B). A height H1 of the dam structure 140 is greater than a height H2 of the second insulating member 153. As a result, a level of an upper surface of the dam structure 140 is formed to be higher than a level of a lower surface of the first semiconductor die 150. The height H2 may corresponds to the height of the stack of the first bonding pad 124, the first connection member 152, and the first connection pad 151. In one or more embodiments, the dam structure 140 may include a high molecular (polymer) material or a metal material.

A first dam structure 140A of the dam structure 140 is disposed between the first connection members 152 below the first semiconductor die 150 and the second connection members 162 below the second semiconductor die 160A next to a first side surface of the first semiconductor die 150. A second dam structure 140B of the dam structure 140 is disposed between the first connection members 152 below the first semiconductor die 150 and the third connection members 163 below the second semiconductor die 160B next to a second side surface opposite to the first side surface of the first semiconductor die 150.

The first semiconductor die 150 is disposed on the interposer 120. The first semiconductor die 150 is disposed side by side with the second semiconductor die 160. The first semiconductor die 150 is electrically connected to the interposer 120 through first connection members 152. The first semiconductor die 150 includes the first connection pads 151. The first connection pads 151 are disposed on the first connection members 152. Each of the first connection pads 151 is electrically connected to the first connection member 152. In one or more embodiments, the first semiconductor die 150 may include a logic die. In one or more embodiments, the first semiconductor die 150 may include an ASIC. In one or more embodiments, the first semiconductor die 150 may include a system on chip (SoC). In one or more embodiments, the first semiconductor die 150 may include at least one of a central processing unit (CPU) and a graphics processing unit (GPU).

Each of the first connection members 152 is disposed between the first bonding pad 124 and the first connection pad 151 of the first semiconductor die 150. Each of the first connection members 152 electrically connects the first connection pad 151 of the first semiconductor die 150 to the first bonding pad 124. In one or more embodiments, the first connection members 152 may include micro bumps or solder balls. In one or more embodiments, the first connection members 152 may include at least one of tin, silver, lead, nickel, copper, or alloys thereof.

The second insulating member 153 is disposed between the interposer 120 and the first semiconductor die 150 in a vertical direction, and between the first dam structure 140A and the second dam structure 140B in a horizontal direction. The second insulating member 153 surrounds and protects the first bonding pads 124, the first connection pads 151, and the first connection members 152. In one or more embodiments, the second insulating member 153 may include the CUF. In one or more embodiments, the second insulating member 153 may include a material with a lower viscosity than the molding material 170.

The second semiconductor die 160 is disposed on the interposer 120. The second semiconductor die 160 is disposed side by side with the first semiconductor die 150. In one or more embodiments, the one or more second semiconductor dies 160A may be disposed next to the first side surface of the first semiconductor die 150. In one or more embodiments, the one or more second semiconductor dies 160B may be disposed next to the second side surface opposite to the first side surface of the first semiconductor die 150. The one or more second semiconductor dies 160A are electrically connected to the interposer 120 through the second connection members 162. The one or more second semiconductor dies 160B are electrically connected to the interposer 120 through the third connection members 163.

The one or more second semiconductor dies 160A and 160B each include the second connection pads 161. The second connection pads 161 are disposed on the second connection members 162 and on the third connection members 163. Each of the second connection pads 161 is electrically connected to the second connection member 162 or the third connection members 163. In one or more embodiments, the second semiconductor die 160 may include a HBM. The HBM is a high-performance three-dimensional (3D) stacked dynamic random access memory RAM (DRAM). The HBM may be manufactured by forming one memory stack by vertically stacking memory dies on a buffer chip by performing hybrid bonding or using a micro bump, and molding one memory stack with a second molding material (a molding material different from the molding material 170).

Each of the second connection members 162 is disposed between the second bonding pad 125 and the second connection pad 161 of the one or more second semiconductor dies 160A. Each of the second connection members 162 electrically connects the second connection pad 161 of the one or more second semiconductor dies 160A to the second bonding pad 125. In one or more embodiments, the second connection members 162 may include micro bumps or solder balls. In one or more embodiments, the second connection members 162 may include at least one of tin, silver, lead, nickel, copper, or alloys thereof.

Each of the third connection members 163 is disposed between the second bonding pad 125 and the second connection pad 161 of the one or more second semiconductor dies 160B. Each of the third connection members 163 electrically connects the second connection pad 161 of the one or more second semiconductor dies 160B to the second bonding pad 125. In one or more embodiments, the third connection members 163 may include micro bumps or solder balls. In one or more embodiments, the third connection members 163 may include at least one of tin, silver, lead, nickel, copper, or alloys thereof.

A molding material (e.g., the molding material 170) covers the first semiconductor die 150, the second semiconductor die 160, the dam structure 140, the second insulating member 153, the second bonding pads 125, the second connection pads 161, the second connection members 162, and the third connection members 163 on the interposer 120. The molding material 170 protects the first semiconductor die 150, the second semiconductor die 160, the dam structure 140, the second insulating member 153, the second bonding pads 125, the second connection pads 161, the second connection members 162, and the third connection members 163 from an external environment, thereby ensuring electrical or mechanical stability of the semiconductor package 100. In one or more embodiments, the molding material 170 may include a material with a higher viscosity than the second insulating member 153. The second insulating member 153 may be excluded from covering the second connection members 162, unlike the first connection members 152 being covered by the second insulating member 153.

Semiconductor packages in the related art use an insulating member (e.g., an underfill member) between an interposer and a HBM. The HBM is molded twice, once with a second molding material and again with a first molding material. Since the first molding material, the second molding material, and the insulating member have different physical properties, the adhesion weakens at the contact points of the first molding material, the second molding material, and the insulating member, and therefore delamination may occur.

One or more embodiments of the disclosure address the delamination issue by replacing the insulating member (e.g., a underfill member) between the interposer and the HBM in the related art. Such a replacement allows the second connection members 162 and the third connection members 163 (which connects the interposer 120 to the second semiconductor die 160) to be covered by a molding material used in a molding process. As a result, the weak contact points where the insulating member used between the interposer and the HBM, the first molding material covering the HBM, and the second molding material within the HBM contact each other may be improved and the delamination may be prevented in embodiments of the disclosure.

In addition, according to the present disclosure, the second bonding pads 125 between the interposer 120 and the second semiconductor die 160, the second connection pads 161, and the second connection members 162, or the second bonding pads 125, the second connection pads 161, and the third connection members 163 may be covered with the molding material 170 used in the molding process other than the insulating member. The second semiconductor die 160 is located outside the semiconductor package 100 in the horizontal direction, and thus, according to the structure of the present disclosure, stress occurring on the outside of the semiconductor package 100 than the center in the horizontal direction due to warpage characteristics that occur in the semiconductor package 100 may be reduced. Therefore, warpage occurring in the semiconductor package 100 may be reduced, and residual stress inside the semiconductor package 100 may be reduced, and thus, a bonding yield may be improved when a bonding process is performed on an external device, etc.

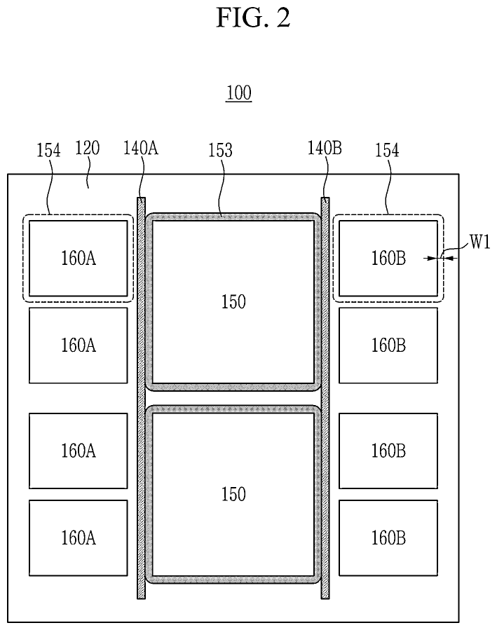

FIG. 2 is a plan view showing a cross section of the semiconductor package 100 of FIG. 1. FIG. 2 is a plan view of the semiconductor package 100 from which the molding material 170 is removed.

Referring to FIG. 2, the semiconductor package 100 includes the interposer 120, the first semiconductor die 150 on the interposer 120, the one or more second semiconductor dies 160A next to a first side surface of the first semiconductor die 150, the one or more second semiconductor dies 160B next to a second side surface of the first semiconductor die 150, the first dam structure 140A, and the second dam structure 140B. The one or more second semiconductor dies 160A are arranged to face the one or more second semiconductor dies 160B across the first semiconductor die 150.

The first dam structure 140A is disposed between the first semiconductor die 150 and the one or more second semiconductor dies 160A next to the first side surface of the first semiconductor die 150. The first dam structure 140A extends along the first side surface of the first semiconductor die 150. The second dam structure 140B is disposed between the first semiconductor die 150 and the one or more second semiconductor dies 160B next to the second side surface of the first semiconductor die 150. The second dam structure 140B extends along the second side surface of the first semiconductor die 150. According to the present disclosure, the dam structure 140 acts as a barrier to prevent an insulating member from flowing towards the second semiconductor die 160.

In one or more embodiments, the first dam structure 140A has an elongated shape that continuously extends between the first semiconductor die 150 and the one or more second semiconductor dies 160A. In one or more embodiments, the second dam structure 140B has an elongated shape that continuously extends between the first semiconductor die 150 and the one second semiconductor die 160B. In one or more embodiments, the first dam structure 140A and the second dam structure 140B may be integrally formed to surround at least a part of all side surfaces of the first semiconductor die 150.

In one or more embodiments of the present disclosure, the second connection members 162 between the interposer 120 and the one or more second semiconductor dies 160A, and the third connection members 163 between the interposer 120 and the one or more second semiconductor dies 160B may be covered with the molding material 170 used in a molding process without using an insulating member 154. Since the insulating member 154 is not used, the insulating member 154 does not occupy a space on a Keep Out Zone (KOZ) outside the second semiconductor die 160, and thus, the size of the interposer 120 may be reduced by a space W1 of the insulating member 154 exposed to the outside of the second semiconductor die 160 of the related art. Therefore, in a process of forming the interposer 120, the number of net dies within a wafer may be increased.

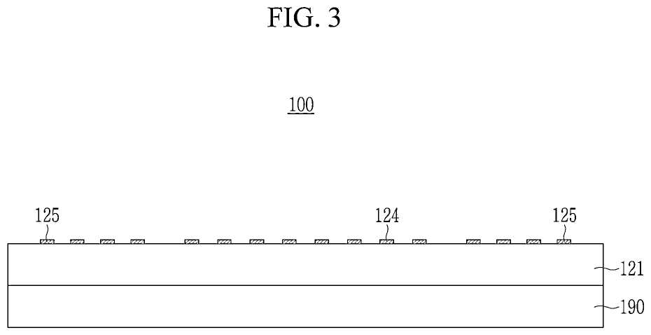

FIGS. 3 to 20 are cross-sectional views for explaining a method of manufacturing the semiconductor package 100 according to one or more embodiments.

FIG. 3 is a cross-sectional view showing a step of forming the first bonding pads 124 and the second bonding pads 125 on the interposer base 121.

Referring to FIG. 3, a carrier 190 is provided. In one or more embodiments, the carrier 190 may include glass or a silicon-based material such as silicon oxide, an organic material, or another material such as aluminum oxide, any combination of these materials, etc. Next, the interposer base 121 is attached onto the carrier 190. In one or more embodiments, the interposer base 121 may be attached onto the carrier 190 by a laser.

Next, the first bonding pads 124 and the second bonding pads 125 are formed on the interposer base 121. The first bonding pads 124 and the second bonding pads 125 are formed by depositing a photoresist on the interposer base 121, selectively exposing and developing the photoresist, forming a photoresist pattern including openings, forming a seed metal layer in the openings of the pattern, and filling the seed metal layer with a conductive material by performing electroplating.

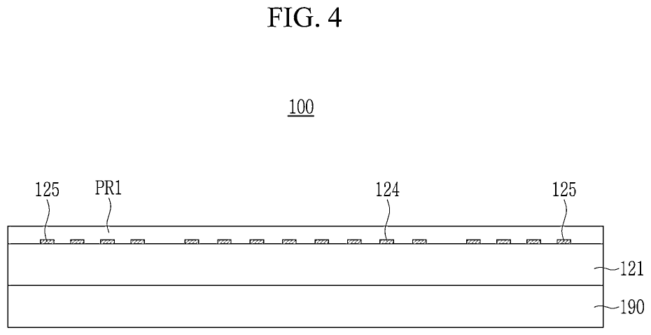

FIGS. 4 to 9 are cross-sectional views for explaining a method of forming the dam structure 140 on the interposer 120, according to one or more embodiments, following FIG. 3. In FIGS. 4 to 9, the dam structure 140 is made of a metal material.

FIG. 4 is a cross-sectional view showing a step of forming a first photoresist PR1 on the interposer base 121, the first bonding pads 124, and the second bonding pads 125.

Referring to FIG. 4, the first photoresist PR1 is formed on the interposer base 121, the first bonding pads 124, and the second bonding pads 125. In one or more embodiments, the first photoresist PR1 may be formed through spin coating. In one or more embodiments, the first photoresist PR1 may include an organic polymer resin. The organic polymer resin may include a photoactive material.

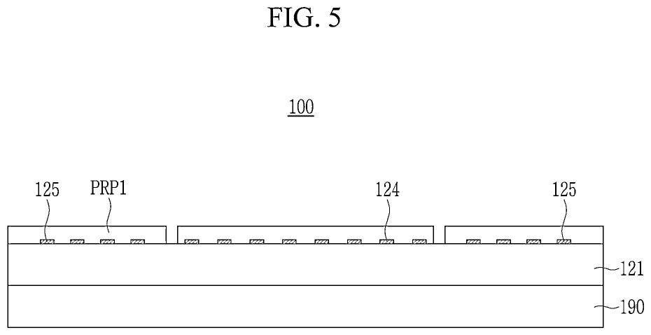

FIG. 5 is a cross-sectional view showing a step of forming a first photoresist pattern PRP1 by exposing and developing the first photoresist PR1.

Referring to FIG. 5, the first photoresist pattern PRP1 is formed by exposing and developing the first photoresist PR1. After the first photoresist pattern PRP1 is formed, a part of an upper surface of the interposer base 121 is exposed.

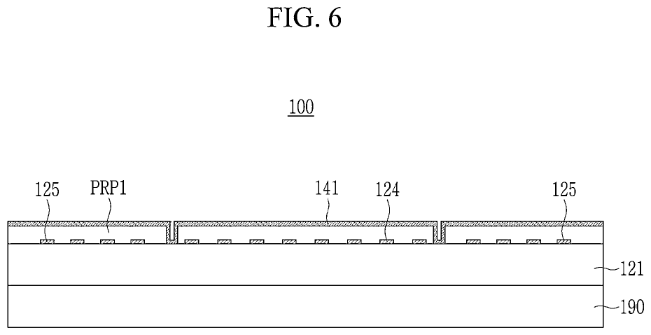

FIG. 6 is a cross-sectional view showing a step of forming a seed metal layer 141.

Referring to FIG. 6, the seed metal layer 141 is formed conformally along the upper surface of the interposer base 121, inner side surfaces of openings of the first photoresist pattern PRP1, and an upper surface of the first photoresist pattern PRP1. In one or more embodiments, the seed metal layer 141 may include copper. In one or more embodiments, the seed metal layer 141 may include a conductive material capable of electroplating. In one or more embodiments, the seed metal layer 141 may be formed by electroless plating. In one or more embodiments, a cleaning process or a metal catalyst activation pretreatment process may be performed prior to electroless plating. In another embodiment, the seed metal layer 141 may be formed by sputtering.

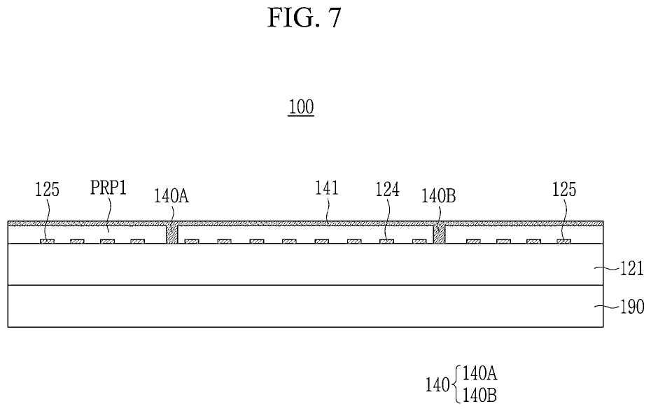

FIG. 7 is a cross-sectional view showing a step of forming the dam structure 140.

Referring to FIG. 7, the dam structure 140 is formed within the openings of the first photoresist pattern PRP1. In one or more embodiments, a process of forming the dam structure 140 may be performed by electroplating. The dam structure 140 is formed by growing a metal film from the previously formed seed metal layer 141 by electroplating. In one or more embodiments, an annealing process may be performed after the dam structure 140 is formed. In one or more embodiments, the dam structure 140 may include copper. In another embodiment, the dam structure 140 may include a conductive material capable of electroplating.

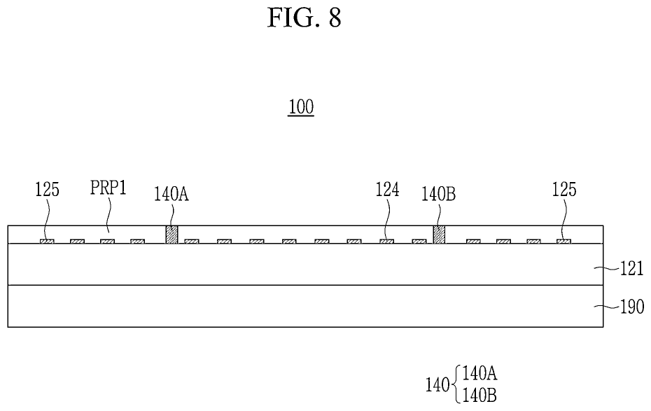

FIG. 8 is a cross-sectional view showing a step of performing a chemical mechanical polishing (CMP) process on the metal film formed on the upper surface of the first photoresist pattern PRP1.

Referring to FIG. 8, in order to remove the seed metal layer 141 and the metal film on the upper surface of the first photoresist pattern PRP1, the CMP process is performed on the seed metal layer 141 and the metal film on the upper surface of the first photoresist pattern PRP1.

After the CMP process is performed, an upper surface of the dam structure 140 is exposed.

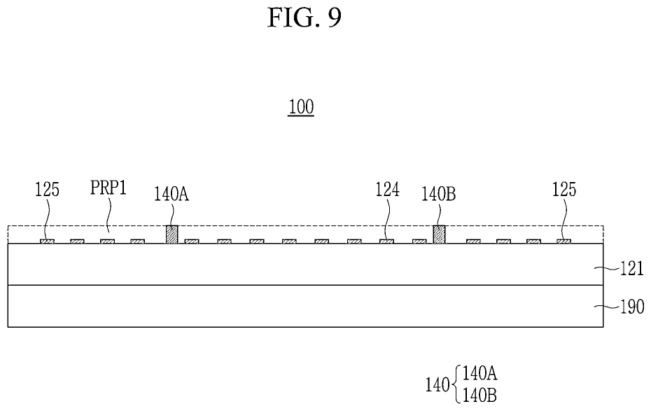

FIG. 9 is a cross-sectional view showing a step of removing the first photoresist pattern PRP1.

Referring to FIG. 9, the first photoresist pattern PRP1 is removed. In one or more embodiments, the first photoresist pattern PRP1 may be removed by at least one of etching, ashing, and stripping.

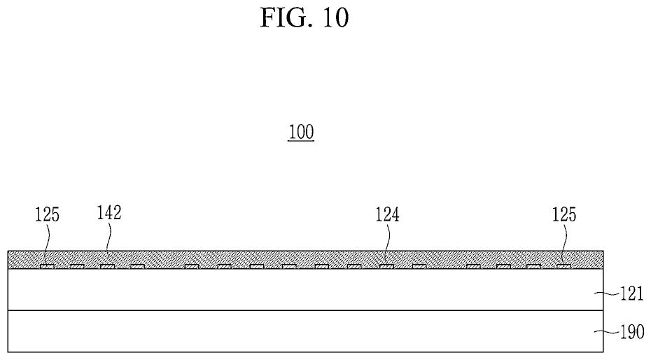

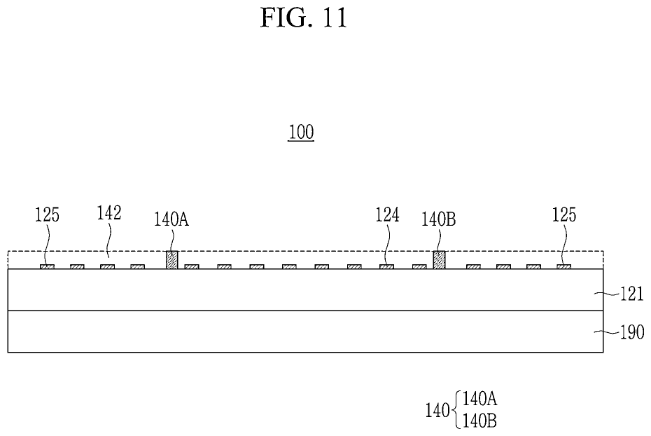

FIGS. 10 and 11 are cross-sectional views for explaining a method of forming the dam structure 140 on the interposer 120, according to one or more embodiments, following FIG. 3. In FIGS. 10 to 14, the dam structure 140 is made of a polymer material.

FIG. 10 is a cross-sectional view showing a step of forming a polymer 142 on the interposer base 121, the first bonding pads 124, and the second bonding pads 125.

Referring to FIG. 10, the polymer 142 is formed on the interposer base 121, the first bonding pads 124, and the second bonding pads 125. In one or more embodiments, the polymer 142 may include a photoimageable dielectric (PID). As one or more embodiments, the polymer 142 may include a polyimide-based photoimageable polymer, a novolak-based photoimageable polymer, polybenzoxazole, a silicone-based polymer, an acrylate-based polymer, or an epoxy-based polymer. In one or more embodiments, the polymer 142 may be formed through spin coating.

FIG. 11 is a cross-sectional view showing a step of forming the dam structure 140 by exposing and developing the polymer 142.

Referring to FIG. 11, the dam structure 140 is formed by exposing and developing the polymer 142.

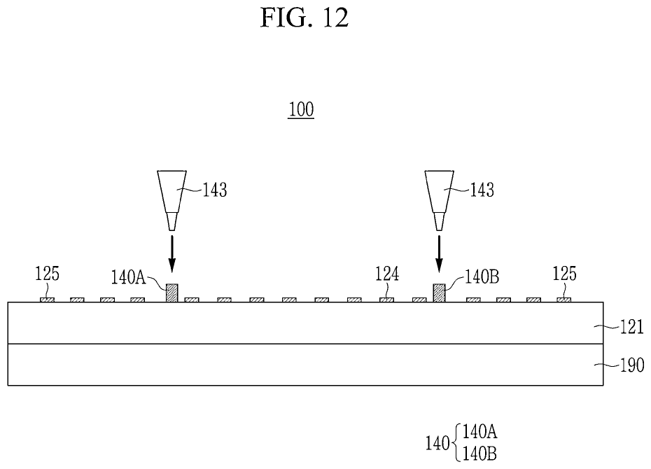

FIG. 12 is a cross-sectional view for explaining a method of forming the dam structure 140 on the interposer 120 according to one or more embodiments, following FIG. 3. In FIG. 12, the dam structure 140 is made of a curable ink material or epoxy resin.

FIG. 12 is a cross-sectional view showing a step of forming the dam structure 140 according to one or more embodiments.

Referring to FIG. 12, in one or more embodiments, the dam structure 140 is formed by an inkjet method. The inkjet method includes ejecting and printing curable ink from an inkjet head through a nozzle 143. In another embodiment, the dam structure 140 is formed by spraying epoxy resin through the nozzle (e.g., an injection nozzle or a dispensing nozzle) 143.

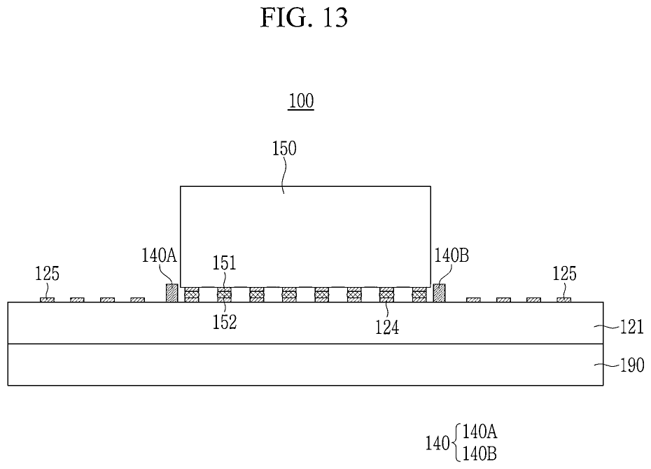

FIG. 13 is a cross-sectional view showing a step of mounting the first semiconductor die 150 on the first bonding pads 124 of the interposer base 121.

Referring to FIG. 13, the first semiconductor die 150 is mounted on the first bonding pads 124 of the interposer base 121, with the first connection pads 151 and the first connection members 152 between the first semiconductor die 150 and the interposer base 121. In one or more embodiments, the first semiconductor die 150 is mounted on the first bonding pads 124 of the interposer base 121 by flip chip bonding. The first connection pads 151 of the first semiconductor die 150 are bonded onto the first bonding pads 124 of the interposer base 121 by the first connection members 152, so that the first semiconductor die 150 and the interposer base 121 are electrically connected to each other.

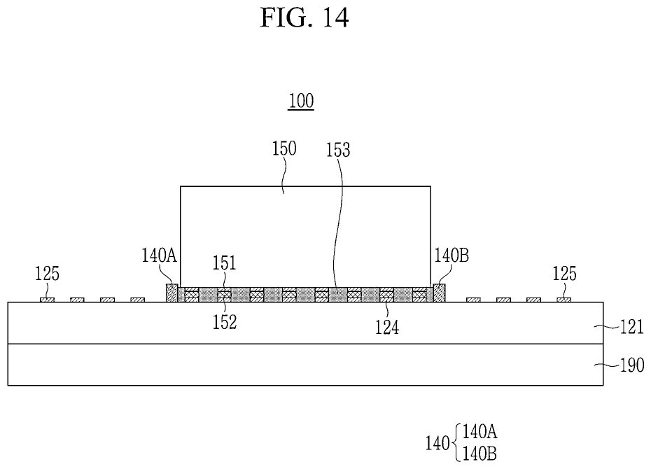

FIG. 14 is a cross-sectional view showing a step of applying the second insulating member 153 between the first dam structure 140A and the second dam structure 140B.

Referring to FIG. 14, the second insulating member 153 is applied between the interposer base 121 and the first semiconductor die 150, and between the first dam structure 140A and the second dam structure 140B. In one or more embodiments, the second insulating member 153 may be applied by a CUF process. The second insulating member 153 has a relatively low viscosity compared to the molding material, and may be applied by using a CUF method. The second insulating member 153 does not flow in a direction in which the second semiconductor die 160 is located due to the first dam structure 140A and the second dam structure 140B. The second insulating member 153 surrounds and protects the first bonding pads 124, the first connection pads 151, and the first connection members 152. In one or more embodiments, the second insulating member 153 may include a CUF material. In one or more embodiments, the second insulating member 153 may include an epoxy resin and a first silica filler.

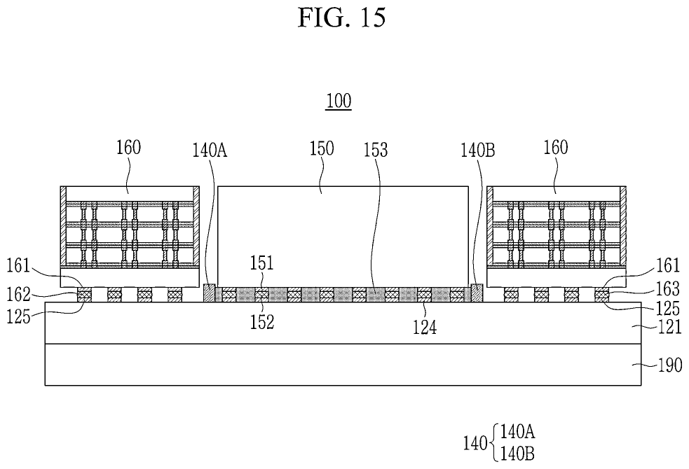

FIG. 15 is a cross-sectional view showing a step of mounting the second semiconductor die 160 on the second bonding pads 125 of the interposer base 121.

Referring to FIG. 15, the second semiconductor die 160 is mounted on the second bonding pads 125 of the interposer base 121. In one or more embodiments, the second semiconductor die 160 is mounted on the second bonding pads 125 of the interposer base 121 by flip chip bonding. The second connection pads 161 of the second semiconductor die 160 are bonded onto the second bonding pads 125 of the interposer base 121 by the second connection members 162 or the third connection members 163, so that the second semiconductor die 160 and the interposer base 121 are electrically connected to each other.

In another embodiment, the order of FIGS. 14 and 15 may be changed. Specifically, in FIG. 14, although the step of applying the second insulating member 153 between the first dam structure 140A and the second dam structure 140B after mounting the first semiconductor die 150 on the interposer 120 and before mounting the second semiconductor die 160 thereon has been shown and described, a step of applying the second insulating member 153 between the first dam structure 140A and the second dam structure 140B after mounting the first semiconductor die 150 and the second semiconductor die 160 on the interposer 120 may be performed.

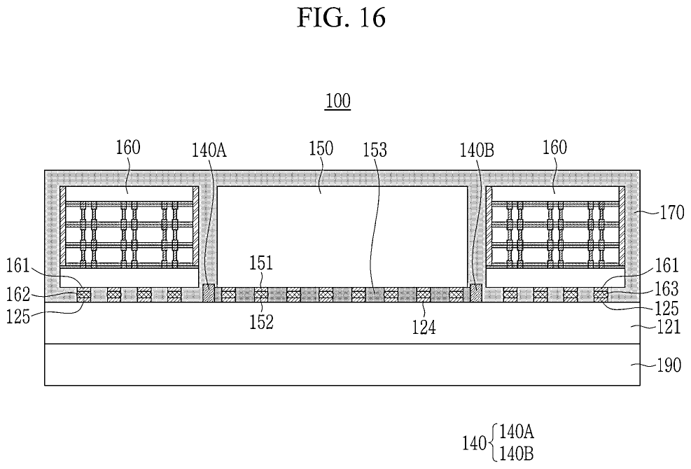

FIG. 16 is a cross-sectional view showing a step of molding, on the interposer base 121, the first semiconductor die 150, the second semiconductor die 160, the dam structure 140, the second insulating member 153, the second bonding pads 125, the second connection pads 161, the second connection members 162, and the third connection members 163.

Referring to FIG. 16, on the interposer base 121, the first semiconductor die 150, the second semiconductor die 160, the dam structure 140, the second insulating member 153, the second bonding pads 125, the second connection pads 161, the second connection members 162, and the third connection members 163 are covered with the molding material 170. The second bonding pads 125, the second connection pads 161, the second connection members 162, and the third connection members 163 are covered with the molding material 170 other than an insulating member. A process of molding the first semiconductor die 150 and the second semiconductor die 160 and a molded underfill (MUF) process of covering the second bonding pads 125, the second connection pads 161, the second connection members 162, and the third the connecting members 163 are simultaneously performed.

In one or more embodiments, the molding process with the molding material 170 may include a compression molding process. The molding material 170 has a relatively high viscosity compared to the second insulating member 153, and the compression molding process is performed. In one or more embodiments, the molding material 170 may include epoxy molding compound (EMC). In one or more embodiments, the molding material 170 may include an epoxy resin and a second silica filler. In one or more embodiments, the molding material 170 may include an epoxy resin, a second silica filler, and an alumina filler. In one or more embodiments, the particle size of the second silica filler of the molding material 170 may be larger than the particle size of the first silica filler of the second insulating member 153.

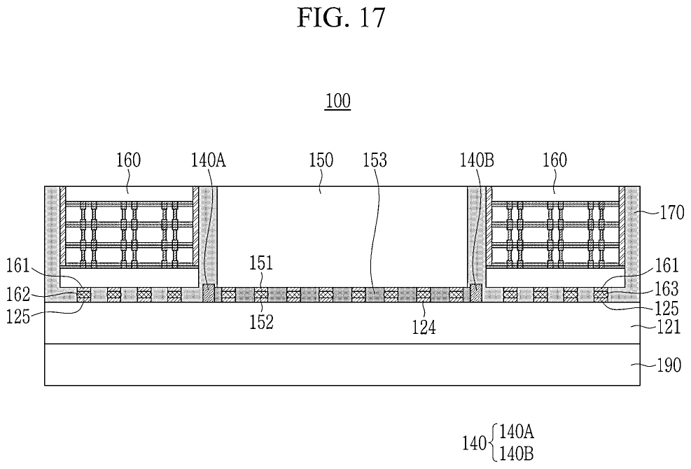

FIG. 17 is a cross-sectional view showing a step of performing a CMP process on the molding material 170.

Referring to FIG. 17, an upper surface of the molding material 170 may be polished by performing the CMP process to match a level of the upper surface of the molding material 170. After performing the CMP process, upper surfaces of the first semiconductor die 150 and the second semiconductor die 160 are exposed.

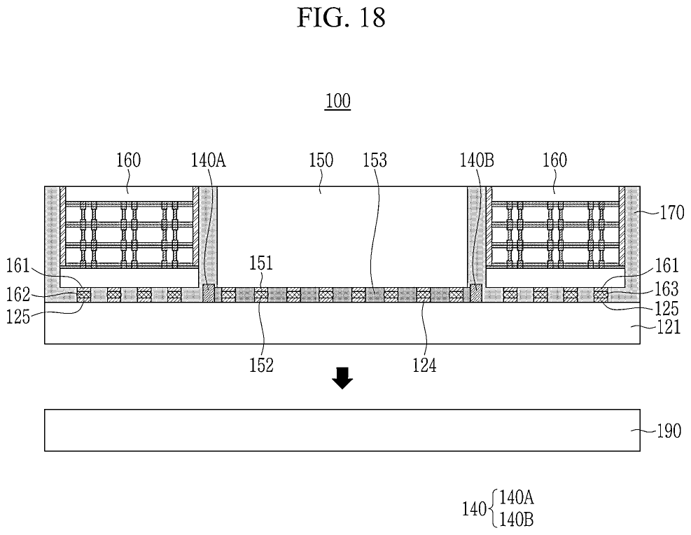

FIG. 18 is a cross-sectional view showing a step of removing the carrier 190 from the interposer base 121.

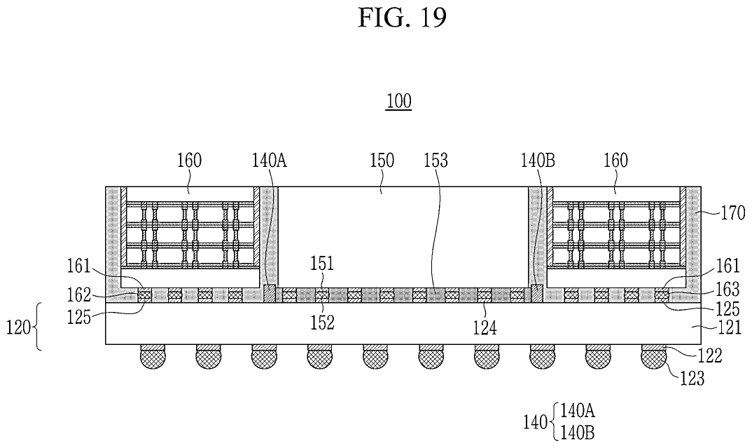

Referring to FIG. 18, the carrier 190 is removed from the interposer base 121. FIG. 19 is a cross-sectional view showing a step of forming the connection pads 122 and the connection members 123 on the lower surface of the interposer base 121.

Referring to FIG. 19, the connection pads 122 are formed on the lower surface of the interposer base 121, and the connection members 123 are formed on the lower surface of the connection pads 122.

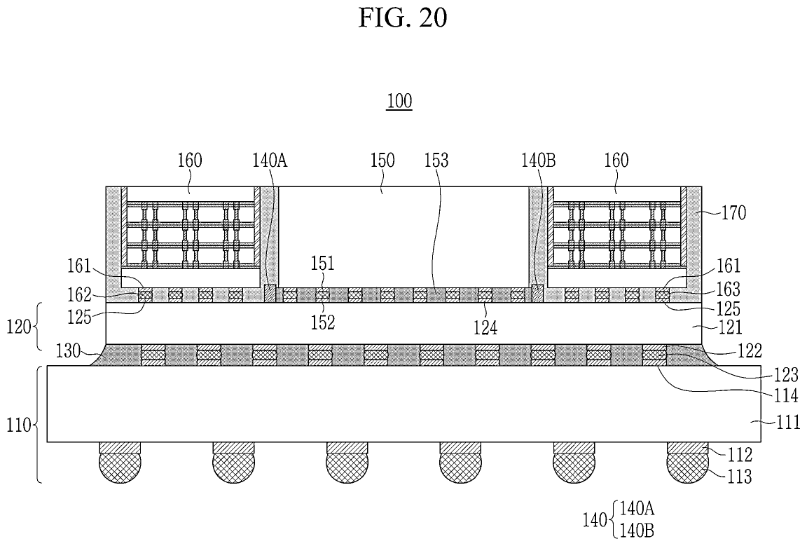

FIG. 20 is a cross-sectional view showing a step of mounting the interposer 120 on the substrate 110.

Referring to FIG. 20, the interposer 120 is mounted on the substrate 110 by performing flip chip bonding.

The foregoing exemplary embodiments are merely exemplary and are not to be construed as limiting. The present teaching can be readily applied to other types of apparatuses. Also, the description of the exemplary embodiments is intended to be illustrative, and not to limit the scope of the claims, and many alternatives, modifications, and variations will be apparent to those skilled in the art.

What is claimed is:

1. A semiconductor package comprising:
an interposer;
a first semiconductor die and a second semiconductor die, the first and the second semiconductor dies being disposed on the interposer;
a plurality of first connection members between the interposer and the first semiconductor die;
a plurality of second connection members between the interposer and the second semiconductor die;
a dam structure between the plurality of first connection members and the plurality of second connection members;
an insulating member covering the plurality of first connection members between the interposer and the first semiconductor die; and
a molding material covering the first semiconductor die, the second semiconductor die, and the plurality of second connection members on the interposer.

2. The semiconductor package of claim 1, wherein:
the insulating member comprises a capillary underfill (CUF) material.

3. The semiconductor package of claim 1, wherein:
the molding material comprises an epoxy molding compound (EMC).

4. The semiconductor package of claim 1, wherein:
the insulating member comprises an epoxy resin and a first silica filler,
the molding material comprises an epoxy resin and a second silica filler, and
a particle size of the first silica filler is less than a particle size of the second silica filler.

5. The semiconductor package of claim 4, wherein:
the molding material further comprises an alumina filler.

6. The semiconductor package of claim 1, wherein:
the dam structure comprises a polymer material.

7. The semiconductor package of claim 1, wherein:
the dam structure comprises a metal material.

8. The semiconductor package of claim 1, wherein:
a height of the dam structure is greater than a height of the insulating member.

9. The semiconductor package of claim 1, wherein:
the dam structure has an elongated shape and extends along a side surface of the first semiconductor die.

10. A semiconductor package comprising:
an interposer;
a first semiconductor die and second semiconductor dies, the first and the second semiconductor dies being disposed on the interposer, the second semiconductor dies comprising a first-side second semiconductor die and a second-side second semiconductor die that are positioned on two opposing sides of the first semiconductor die to face each other across the first semiconductor die;
a plurality of first connection members between the interposer and the first semiconductor die;
a plurality of second connection members between the interposer and the first-side second semiconductor die;
a plurality of third connection members between the interposer and the second-side second semiconductor die;
a first dam structure on the interposer and between the plurality of first connection members and the plurality of second connection members;
a second dam structure on the interposer and between the plurality of first connection members and the plurality of third connection members;
an insulating member covering the plurality of first connection members between the interposer and the first semiconductor die; and
a molding material covering the first semiconductor die, the first-side second semiconductor die, the second-side semiconductor die, the plurality of second connection members, and the plurality of third connection members on the interposer.

11. The semiconductor package of claim 10, wherein:
the interposer comprises a silicon interposer, an organic interposer, or a composite interposer.

12. The semiconductor package of claim 10, wherein:
the first semiconductor die comprises an application specific integrated circuit (ASIC).

13. The semiconductor package of claim 10, wherein:
the second semiconductor die comprises a high bandwidth memory (HBM).

14. A method of manufacturing a semiconductor package, the method comprising:
forming a plurality of first bonding pads and a plurality of second bonding pads on a substrate;
forming a dam structure between the plurality of first bonding pads and the plurality of second bonding pads on the substrate;
bonding a first semiconductor die to the plurality of first bonding pads by using a plurality of first connection members, and bonding a second semiconductor die to the plurality of second bonding pads by using a plurality of second connection members;
applying an insulating member to cover the plurality of first bonding pads and the plurality of first connection members; and
covering the first semiconductor die, the second semiconductor die, the plurality of second bonding pads, and the plurality of second connection members with a molding material on the substrate.

15. The method of claim 14, wherein:
the forming of the dam structure is performed by an inkjet process.

16. The method of claim 14, wherein:
the forming of the dam structure is performed by a dispensing process.

17. The method of claim 14, wherein:
the forming of the dam structure comprises
forming a photoimageable dielectric (PID) on the substrate; and
performing an exposing and developing process on the PID.

18. The method of claim 14, wherein:
the forming of the dam structure comprises
forming a photoresist pattern on the substrate;
forming a seed metal layer within openings of the photoresist pattern; and
performing electroplating.

19. The method of claim 14, wherein:
the applying of the insulating member is performed by a capillary underfill (CUF) process.

20. The method of claim 14, wherein:
the covering with the molding material is performed by a compression molding process.
